(19) United States
(12) Patent Application Publication
(10) Pub. No.: US 2026/0122796 A1
(43) Pub. Date: Apr. 30, 2026

(54) LIGHT BLOCKING AIR VENT

(71) Applicant: DELL PRODUCTS L.P., Round Rock, TX (US)

(72) Inventors: Sandor Farkas, Round Rock, TX (US); Michael Stumpf, Cedar Park, TX (US)

(21) Appl. No.: 18/928,001

(22) Filed: Oct. 26, 2024

(51) Int. Cl. H05K 5/02; C09D 5/32

(52) U.S. Cl. CPC H05K 5/0213; C09D 5/32

(57) ABSTRACT

A light blocking air vent for an information handling system includes top and bottom surfaces, and multiple components. The multiple components include first and second components. The first component is in physical communication with the top surface and the second component is in physical communication with the bottom surface. The multiple components create channels within the light blocking air vent. The channels allow airflow through the light blocking air vent, and the components prevent light from traveling from one edge of the light blocking air vent to another edge of the light blocking air vent.

### FIELD OF THE DISCLOSURE

The present disclosure generally relates to information handling systems, and more particularly relates to an information handling system with a light blocking air vent.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

A light blocking air vent for an information handling system includes top and bottom surfaces, and multiple components. The multiple components include first and second components. The first component is in physical communication with the top surface and the second component is in physical communication with the bottom surface. The multiple components may create channels within the light blocking air vent. The channels may allow airflow through the light blocking air vent, and the components may prevent light from traveling from one edge of the light blocking air vent to another edge of the light blocking air vent.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a diagram of a portion of an information handling according to at least one embodiment of the present disclosure;

FIGS. 2-5 are diagrams of different embodiments of a light blocking air vent for an information handling system according to at least one embodiment of the present disclosure; and

FIG. 6 is a block diagram of a general information handling system according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

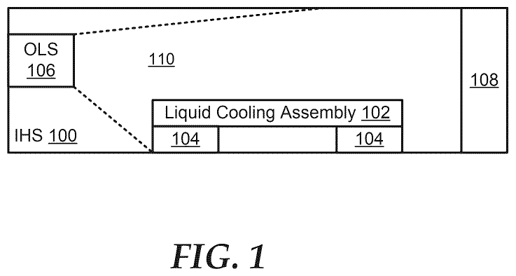

FIG. 1 illustrates an information handling system 100 according to at least one embodiment of the present disclosure. For purposes of this disclosure, an information handling system can include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an information handling system may be a personal computer (such as a desktop or laptop), tablet computer, mobile device (such as a personal digital assistant (PDA) or smart phone), server (such as a blade server or rack server), a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, touchscreen and/or a video display. The information handling system may also include one or more buses operable to transmit communications between the various hardware components.

Information handling system 100 includes a liquid cooling assembly 102, multiple processors 104, and an optical leak senor (OLS) 106, and an air vent 108. Liquid cooling assembly 102 includes a coolant supply line coupler 110 and a coolant return line coupler 112, coolant supply lines 114, coolant return lines 116, and multiple cold plates 118. Information handling system 100 may further include an air filter in physical communication with air vent 108. In an example, the air filter may be utilized without affecting how liquid cooling assembly 102 and OLS 106 operation within information handling system 100. Information handling system 100 may include additional components without varying from the scope of this disclosure.

In certain examples, liquid cooling assembly 102 may be coupled to a pump, which in turn may circulate a coolant such as water or other liquid (e.g., water plus additives) through coolant supply lines, cold plates 118, and coolant return lines. This circulation of the coolant may provide liquid cooling to multiple components of information handling system 100, including memory, CPUs 104, GPUs, as well as other components. The coolant circulates in a closed loop within the housing of information handling system 100 and absorbs heat from the components to cool the components via cold plates. Liquid cooling leverages the exceptional thermal capacity of liquid to absorb and remove heat created by new high-power processors 104. Cold plates may be attached directly to processors 104, enabling the coolant to capture and convey heat to a heat exchanger located, for example, in a rack or row. In a datacenter, for example, the heat load may be removed from the datacenter via a liquid loop, potentially bypassing the expensive chiller system. Replacing or supplementing conventional air-cooling with more-efficient liquid cooling may enhance the operational efficiency of the datacenter.

Notwithstanding the advantages of liquid cooling, there is the possibility that one or more components of the liquid cooling assembly may develop leaks over time due to vibration, thermal cycles, aging, misalignment of heat exchangers or cold plates, or the like. Any leak that exposes the components of the information handling system to liquid can cause corrosion or damage to the circuitry within the housing of information handling system 100. In certain arrangements, a leak occurring in one information handling system also may damage one or more nearby information handling systems if the systems are sufficiently close to one another. For example, a leak may occur in one of multiple servers stacked on a vertical rack (an increasingly common configuration). If the leak is not detected early enough, the coolant may spill out of one server and adversely affect one or more servers below it on the vertical rack.

In an example, OLS 106 may detect a coolant leak within liquid cooling assembly 102 of information handling system 100. OLS 106 includes internal illuminator, photodetector, and signal processor communicatively coupled to photodetector. In certain embodiments, OLS 106 may also include actuator for controlling the internal illuminator. OLS, in certain arrangements, may be integrated into a motherboard of an information handling system. In other arrangements, OLS 106 may be a stand-alone device that connects internally to an information handling system, for example by connecting to an internal partition, side region, cover, or other part of the information handling system.

In certain examples, OLS 106 detects a potential leak within liquid cooling assembly 102 of information handling system 100 based on the information conveyed by the nature of the light detected by photodetector when light 110 emitted by internal illuminator is reflected to the photodetector. In certain embodiments, internal illuminator includes one or more light emitting diodes (LEDs). The light 110 emitted by internal illuminator may have a specific wavelength or may form a spectrum of light having different frequencies and corresponding wavelengths. In certain embodiments, the emitted light 110 is specifically ultraviolet (UV) light. In an example, the dye may fluoresce when illuminated by light 110, such as UV light, emitted by internal illuminator and is detectable by photodetector. Actuator, included in certain embodiments, may intermittently activate internal illuminator, causing the internal illuminator to emit pulses of light 110 in a predetermined pattern. In other embodiments, actuator may cause internal illuminator to emit a constant light emission.

In an example, air vent 108 of information handling system 100 may enable airflow within the information handling system to provide additional cooling to the components, including processors 104, of the information handling system. OLS 106 may flood the chassis of information handling system 100 with UV light 110. However, UV light 110 may cause eye health concerns if the UV light leaks or escapes from within the chassis of information handling system 100. Additionally, the operation of OLS 106 may be improved, such as sensor response, by preventing the ambident light located outside of information handling system 100 from entering within the chassis of the information handling system. Thus, air vent 108 may improve OLS 106 operation while allowing airflow from outside of the chassis into the chassis of information handling system. In this situation, air vent 108 may need to be a UV light 110 blocking air vent as will be described herein.

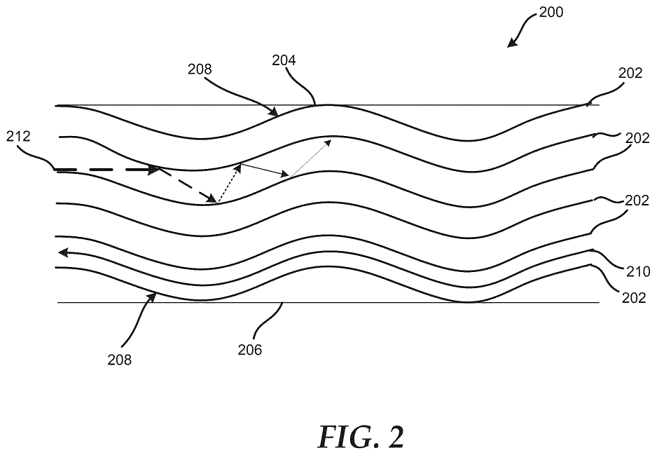

FIG. 2 illustrates a light blocking air vent 200 according to at least one embodiment of the present disclosure. Light blocking air vent 200 includes multiple fins or directional members 202, a top surface 204, and a bottom surface 206. In an example, each of fins 202 may include a light absorbing coating 208. In an example, one edge of light blocking air vent 200 may be located near a cool aisle of a server rack and the other edge of the light blocking air vent may be located near an interior portion of a chassis of an information handling system, such as information handling system 100 of FIG. 1. Light blocking air vent 200 may include components without varying from the scope of this disclosure.

In an example, fins 202 may be formed in any suitable shape to allow air flow to move from outside of an information handling system, such as information handling system 100 of FIG. 1, into the chassis of the information handling system. However, the shape of fins 202 may prevent light from traveling into or out of the chassis of the information handling system. In this configuration, fins 202 may prevent the UV light from escaping the chassis of the information handling system, which in turn may eliminate eye concerns for individuals working near the information handling system. Also, the configuration of fins 202 may prevent the light outside of the information handling system from entering the chassis of the information handling system, which in turn may prevent this light from impacting the operation of an OLS, such as OLS 106 of information handling system 100 in FIG. 1.

Based on fins 202 blocking of the light outside of the information handling system from entering the chassis, the fins may improve a tamper resistance of the OLS of the information handling system. For example, if an individual attempts to corrupt or tamper with the operation of the OLS by shining a light into the chassis via light blocking air vent 200, fins 202 may block this light to prevent the attempted tampering. Thus, fins 202 may improve the operation of the OLS of the information handling system.

As illustrated, each fin 202 may be sinusoidal in shape, which may be modulated in a plane formed by the interior edge and cold aisle edge as the first axis and top surface 204 and bottom surface 206 as the second axis. In an example, the sinusoidal shape of each fin 202 may enable airflow 210 to easily flow from the cold aisle, through light blocking air vent 200, and into the interior of the chassis of the information handling system. While only a single arrow representing airflow 210 is illustrated in FIG. 2, the airflow may flow through each of the channels of light blocking air vent 200.

In certain examples, the modulation of fins 202 may be any suitable amount to create the channel. In a particular embodiment, the modulation of fins 202 may affect how light 212 travels through the fins of light blocking air vent 200. If the modulation of fins 202 creates shallow and long channels within light blocking air vent 200, the number of reflections for UV light 212 may increase. As the number of reflections increases, the intensity of the light may reduce until the light stops traveling within the channels.

In an example, coating 208 of fins 202 may also affect the transmission or blocking of light within light blocking air vent 200. Coating 208 of fins 202 may be any suitable UV absorbent material including, but not limited to, titanium oxide and zinc oxide. Additionally, coating 208 may have any suitable finish absorb light 212 that travels through fins 202. For example, coating 208 may have a matte finish. A matte finish of coating 208 may absorb light rays, such as UV light rays emitted from an OLS, such as OLS 106 in information handling system 100 of FIG. 1. Also, the matte finish of coating 208 may absorb ambient light rays to prevent light outside of the information handling system from entering into the chassis of the information handling system and affecting the operation of the OLS.

In certain examples, the texture of coating 208 may also affect the transmission or blocking of light within light blocking air vent 200. The texture of coating 208 may be any suitable texture including, but not limited to, mottled and irregular. In an example, a rough texture of coating 208 may disrupt reflections of light rays, such as UV light rays emitted from an OLS, such as OLS 106 in information handling system 100 of FIG. 1. The disruption of reflections of UV light may prevent the light from traveling from the interior of the information handling system, through light blocking air vent 200 and out of the information handling system. Additionally, mottled or irregular texture of coating 208 may prevent ambient light outside of the information handling system from entering into the chassis of the information handling system and affecting the operation of the OLS.

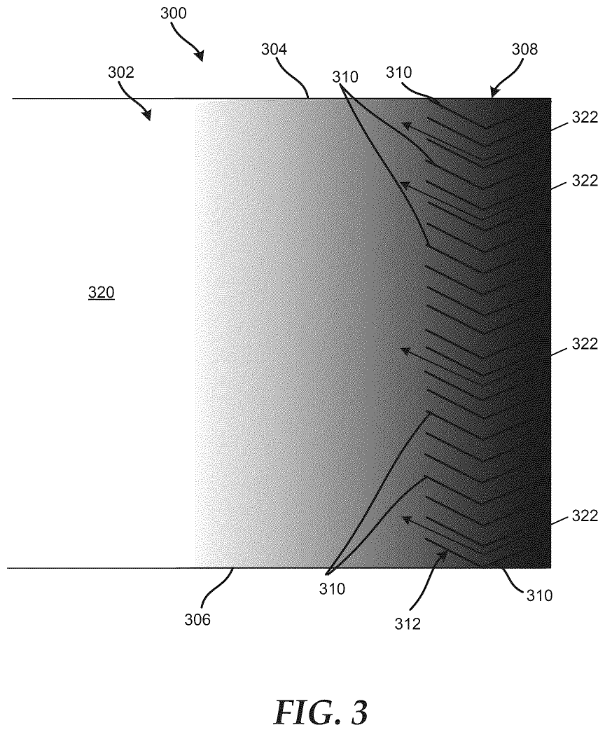

FIG. 3 illustrates a portion of an information handling system 300 including a chassis 302, which in turn includes a top surface 304 and a bottom surface 306. Information handling system 300 further includes a light blocking air vent 308 according to at least one embodiment of the present disclosure. Light blocking air vent 308 includes multiple fins 310. In an example, one of fins 310 may be in physical communication with top surface 304 and another one of the fins may be in physical communication with bottom surface 306. In certain examples, light blocking air vent 200 of FIG. 2 may be inserted within information handling system 300 to perform block light and enable airflow within the information handling system. Information handling system 300 may include additional components without varying from the scope of this disclosure.

In an example, fins 310 may be formed in any suitable shape to allow air flow to move from outside of information handling system 300. However, the shape of fins 310 may prevent light from traveling into or out of chassis 302 of information handling system 300. In this configuration, fins 310 may prevent UV light 320 from escaping chassis 302, which in turn may eliminate eye concerns for individuals working near information handling system 300. Also, the configuration of fins 310 may prevent the light outside of information handling system 300 from entering chassis 302, which in turn may prevent this light from impacting the operation of an OLS, such as OLS 106 of information handling system 100 in FIG. 1.

Based on fins 310 blocking of the light outside of the information handling system from entering the chassis, the fins may improve a tamper resistance of the OLS of the information handling system. For example, if an individual attempts to corrupt or tamper with the operation of the OLS by shining a light into the chassis via light blocking air vent 308, fins 310 may block this light to prevent the attempted tampering. Thus, fins 310 may improve the operation of the OLS of the information handling system.

As illustrated, each fin 310 may be zigzag in shape, varying in a plane formed by the interior edge and cold aisle edge as the first axis and top surface 304 and bottom surface 306 as the second axis. In an example, the zigzag shape of each fin 310 may enable airflow 322 to easily flow from the cold aisle, through light blocking air vent 308, and into the interior of chassis 302. While only a few arrows representing airflow 322 is illustrated in FIG. 3, the airflow may flow through each of the channels of light blocking air vent 308.

In certain examples, the variation of fins 310 may be any suitable amount to create the channels. In a particular embodiment, the variation of fins 310 may affect how light 320 travels through the fins of light blocking air vent 308. If variations of fins 310 create shallow and long channels having multiple variations within light blocking air vent 308, the number of reflections for UV light 320 may increase. As the number of reflections increases, the intensity of the light may reduce until the light stops traveling within the channels.

In an example, coating 312 of fins 310 may also affect the transmission or blocking of light within light blocking air vent 308. Coating 312 of fins 310 may be any suitable UV absorbent material including, but not limited to, titanium oxide and zinc oxide. Additionally, coating 312 may have any suitable finish absorb light 320 that travels through fins 310. For example, coating 312 may have a matte finish. A matte finish of coating 312 may absorb light rays, such as UV light rays emitted from an OLS, such as OLS 106 in information handling system 100 of FIG. 1. Also, the matte finish of coating 312 may absorb ambient light rays to prevent light outside of the information handling system from entering into the chassis of the information handling system and affecting the operation of the OLS.

In certain examples, the texture of coating 312 may also affect the transmission or blocking of light within light blocking air vent 308. The texture of coating 312 may be any suitable texture including, but not limited to, mottled and irregular. In an example, a rough texture of coating 312 may disrupt reflections of light rays, such as UV light rays emitted from an OLS, such as OLS 106 in information handling system 100 of FIG. 1. The disruption of reflections of UV light may prevent the light from traveling from the interior of the information handling system, through light blocking air vent 308 and out of the information handling system. Additionally, mottled or irregular texture of coating 312 may prevent ambient light outside of the information handling system from entering into the chassis of the information handling system and affecting the operation of the OLS.

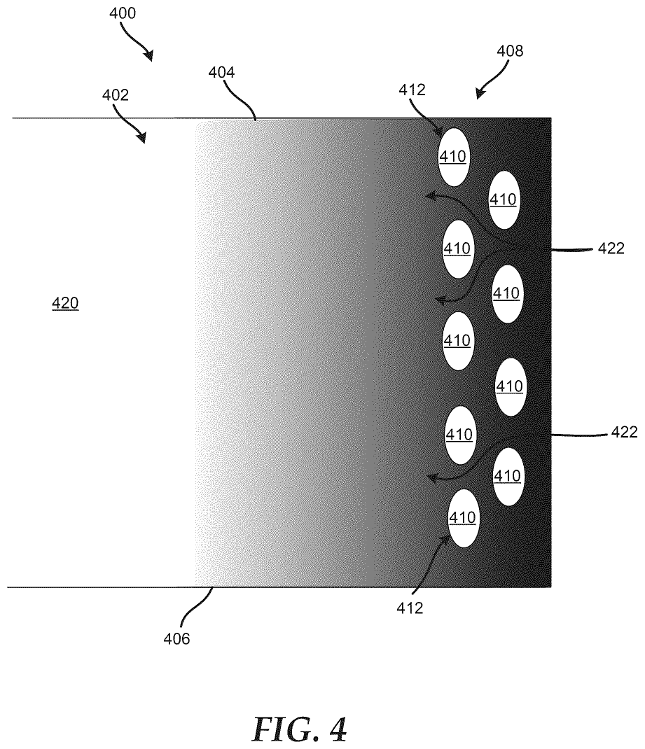

FIG. 4 illustrates a portion of an information handling system 400 including a chassis 402, which in turn includes a top surface 404 and a bottom surface 406. Information handling system 400 further includes a light blocking air vent 408 according to at least one embodiment of the present disclosure. Light blocking air vent 408 includes multiple columns 410. In an example, one of columns 410 may be near top surface 404 and another one of the columns may be near bottom surface 406. In certain examples, light blocking air vent 200 of FIG. 2 may be inserted within information handling system 400 to perform block light and enable airflow within the information handling system. Information handling system 400 may include additional components without varying from the scope of this disclosure.

In an example, columns 410 may be formed in any suitable shape to allow air flow to move from outside of information handling system 400. However, the number and rows of columns 410 may prevent light from traveling into or out of chassis 402 of information handling system 400. In this configuration, columns 410 may prevent UV light 420 from escaping chassis 402, which in turn may eliminate eye concerns for individuals working near information handling system 400. Also, the configuration of columns 410 may prevent the light outside of information handling system 400 from entering chassis 402, which in turn may prevent this light from impacting the operation of an OLS, such as OLS 106 of information handling system 100 in FIG. 1. While only two rows or layers of columns 410 are illustrated and required to effectively block almost all light rays from exiting chassis 402, any suitable number of rows may be utilized within information handling system 400 without varying from the scope of this disclosure.

In certain examples, each column 410 may include gentle curves to prevent turbulence with airflow 422. While only a few arrows representing airflow 422 is illustrated in FIG. 4, the airflow may flow around each of column 410 of light blocking air vent 408. In an example, coating 412 of columns 410 may also affect the transmission or blocking of light within light blocking air vent 408. Coating 412 of columns 410 may be any suitable UV absorbent material including, but not limited to, titanium oxide and zinc oxide. Additionally, coating 412 may have any suitable finish absorb light 420 that travels through columns 410. For example, coating 412 may have a matte finish. A matte finish of coating 412 may absorb light rays, such as UV light rays emitted from an OLS, such as OLS 106 in information handling system 100 of FIG. 1. Also, the matte finish of coating 412 may absorb ambient light rays to prevent light outside of the information handling system from entering into the chassis of the information handling system and affecting the operation of the OLS.

In certain examples, the texture of coating 412 may also affect the transmission or blocking of light within light blocking air vent 408. The texture of coating 412 may be any suitable texture including, but not limited to, mottled and irregular. In an example, a rough texture of coating 412 may disrupt reflections of light rays, such as UV light rays emitted from an OLS, such as OLS 106 in information handling system 100 of FIG. 1. The disruption of reflections of UV light may prevent the light from traveling from the interior of the information handling system, through light blocking air vent 408 and out of the information handling system. Additionally, mottled or irregular texture of coating 412 may prevent ambient light outside of the information handling system from entering into the chassis of the information handling system and affecting the operation of the OLS.

Based on columns 410 blocking of the light outside of the information handling system from entering the chassis, the fins may improve a tamper resistance of the OLS of the information handling system. For example, if an individual attempts to corrupt or tamper with the operation of the OLS by shining a light into the chassis via light blocking air vent 408, columns 410 may block this light to prevent the attempted tampering. Thus, columns 410 may improve the operation of the OLS of the information handling system.

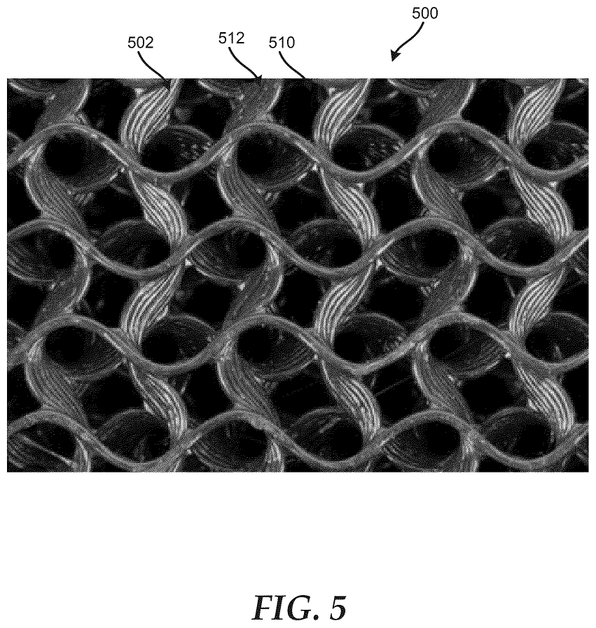

FIG. 5 illustrates a light blocking air vent 500 according to at least one embodiment of the present disclosure. Light blocking air vent 500 be incorporated in any suitable information handling system, such as information handling system 100, 300, or 400 of FIG. 1, 3, or 4. Light blocking air vent 500 includes a spiral pattern 502 to block light from leaving or entering the information handling system. In an example, light blocking air vent 500 may include additional components without varying from the scope of this disclosure.

In certain examples, spiral pattern 502 may be formed in a 3-D pattern similar to gyroid to block light without blocking an airflow. Spiral pattern 502 may modulate along all three axis gently. In an example, spiral pattern 502 may be described as a ‘bundle of straws’ but twisted. Spiral pattern 502 may not create a high air impedance but may prevent light from passing through the spiral.

In an example, spiral pattern 502 may allow air flow to move from outside of information handling system 300. However, spiral pattern 502 may prevent light from traveling into or out of a chassis of information handling system. In this configuration, spiral pattern 502 may prevent UV light from escaping the chassis, which in turn may eliminate eye concerns for individuals working near an information handling system. Also, the configuration of spiral pattern 502 may prevent the light outside of the information handling system from entering the information handling system, which in turn may prevent this light from impacting the operation of an OLS, such as OLS 106 of information handling system 100 in FIG. 1.

In certain examples, spiral pattern 502 may include multiple channels 510. In a particular embodiment, spiral pattern 502 may affect how light travels through light blocking air vent 500.

In an example, coating 512 of spiral pattern 502 may also affect the transmission or blocking of light within light blocking air vent 500. Coating 512 of spiral pattern 502 may be any suitable UV absorbent material including, but not limited to, titanium oxide and zinc oxide. Additionally, coating 512 may have any suitable finish absorb light that travels through spiral pattern 502. For example, coating 512 may have a matte finish. A matte finish of coating 512 may absorb light rays, such as UV light rays emitted from an OLS, such as OLS 106 in information handling system 100 of FIG. 1. Also, the matte finish of coating 512 may absorb ambient light rays to prevent light outside of the information handling system from entering into the chassis of the information handling system and affecting the operation of the OLS.

In certain examples, the texture of coating 512 may also affect the transmission or blocking of light within light blocking air vent 500. The texture of coating 512 may be any suitable texture including, but not limited to, mottled and irregular. In an example, a rough texture of coating 512 may disrupt reflections of light rays, such as UV light rays emitted from an OLS, such as OLS 106 in information handling system 100 of FIG. 1. The disruption of reflections of UV light may prevent the light from traveling from the interior of the information handling system, through light blocking air vent 500 and out of the information handling system. Additionally, mottled or irregular texture of coating 512 may prevent ambient light outside of the information handling system from entering into the chassis of the information handling system and affecting the operation of the OLS.

Based on spiral pattern 502 blocking of the light outside of the information handling system from entering the chassis, the fins may improve a tamper resistance of the OLS of the information handling system. For example, if an individual attempts to corrupt or tamper with the operation of the OLS by shining a light into the chassis via light blocking air vent 500, spiral pattern 502 may block this light to prevent the attempted tampering. Thus, spiral pattern 502 may improve the operation of the OLS of the information handling system.

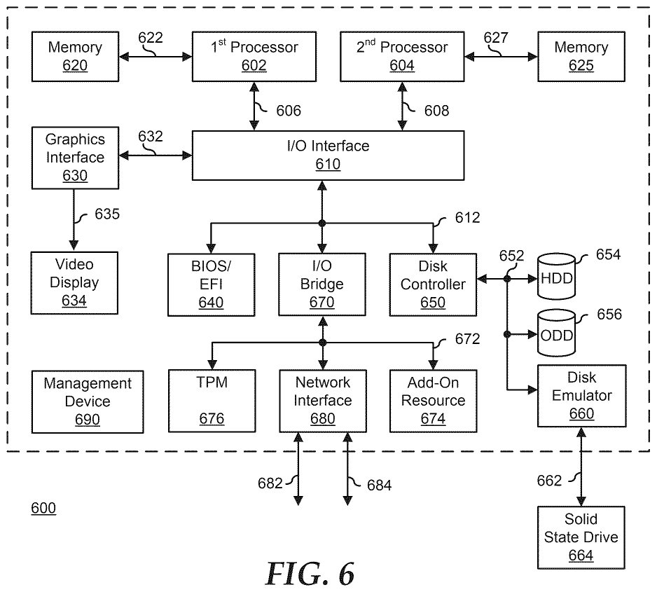

FIG. 6 shows a generalized embodiment of an information handling system 600 according to an embodiment of the present disclosure. Information handling system 600 may be substantially similar to information handling system 100 of FIG. 1. Further, information handling system 600 can include processing resources for executing machine-executable code, such as a central processing unit (CPU), a programmable logic array (PLA), an embedded device such as a System-on-a-Chip (SoC), or other control logic hardware. Information handling system 600 can also include one or more computer-readable medium for storing machine-executable code, such as software or data. Additional components of information handling system 600 can include one or more storage devices that can store machine-executable code, one or more communications ports for communicating with external devices, and various input and output (I/O) devices, such as a keyboard, a mouse, and a video display. Information handling system 600 can also include one or more buses operable to transmit information between the various hardware components.

Information handling system 600 can include devices or modules that embody one or more of the devices or modules described below and operates to perform one or more of the methods described below. Information handling system 600 includes a processors 602 and 604, an input/output (I/O) interface 610, memories 620 and 625, a graphics interface 630, a basic input and output system/universal extensible firmware interface (BIOS/UEFI) module 640, a disk controller 650, a hard disk drive (HDD) 654, an optical disk drive (ODD) 656, a disk emulator 660 connected to an external solid state drive (SSD) 664, an I/O bridge 670, one or more add-on resources 674, a trusted platform module (TPM) 676, a network interface 680, a management device 690, and a power supply 695. Processors 602 and 604, I/O interface 610, memory 620, graphics interface 630, BIOS/UEFI module 640, disk controller 650, HDD 654, ODD 656, disk emulator 660, SSD 664, I/O bridge 670, add-on resources 674, TPM 676, and network interface 680 operate together to provide a host environment of information handling system 600 that operates to provide the data processing functionality of the information handling system. The host environment operates to execute machine-executable code, including platform BIOS/UEFI code, device firmware, operating system code, applications, programs, and the like, to perform the data processing tasks associated with information handling system 600.

In the host environment, processor 602 is connected to I/O interface 610 via processor interface 606, and processor 604 is connected to the I/O interface via processor interface 608. Memory 620 is connected to processor 602 via a memory interface 622. Memory 625 is connected to processor 604 via a memory interface 627. Graphics interface 630 is connected to I/O interface 610 via a graphics interface 632 and provides a video display output 636 to a video display 634. In a particular embodiment, information handling system 600 includes separate memories that are dedicated to each of processors 602 and 604 via separate memory interfaces. An example of memories 620 and 630 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 640, disk controller 650, and I/O bridge 670 are connected to I/O interface 610 via an I/O channel 612. An example of I/O channel 612 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 610 can also include one or more other I/O interfaces, including an Industry Standard Architecture (ISA) interface, a Small Computer Serial Interface (SCSI) interface, an Inter-Integrated Circuit (I2C) interface, a System Packet Interface (SPI), a Universal Serial Bus (USB), another interface, or a combination thereof. BIOS/UEFI module 640 includes BIOS/UEFI code operable to detect resources within information handling system 600, to provide drivers for the resources, initialize the resources, and access the resources. BIOS/UEFI module 640 includes code that operates to detect resources within information handling system 600, to provide drivers for the resources, to initialize the resources, and to access the resources.

Disk controller 650 includes a disk interface 652 that connects the disk controller to HDD 654, to ODD 656, and to disk emulator 660. An example of disk interface 652 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 660 permits SSD 664 to be connected to information handling system 600 via an external interface 662. An example of external interface 662 includes a USB interface, an IEEE 4394 (Firewire) interface, a proprietary interface, or a combination thereof. Alternatively, solid-state drive 664 can be disposed within information handling system 600.

I/O bridge 670 includes a peripheral interface 672 that connects the I/O bridge to add-on resource 674, to TPM 676, and to network interface 680. Peripheral interface 672 can be the same type of interface as I/O channel 612 or can be a different type of interface. As such, I/O bridge 670 extends the capacity of I/O channel 612 when peripheral interface 672 and the I/O channel are of the same type, and the I/O bridge translates information from a format suitable to the I/O channel to a format suitable to the peripheral channel 672 when they are of a different type. Add-on resource 674 can include a data storage system, an additional graphics interface, a network interface card (NIC), a sound/video processing card, another add-on resource, or a combination thereof. Add-on resource 674 can be on a main circuit board, on separate circuit board or add-in card disposed within information handling system 600, a device that is external to the information handling system, or a combination thereof.

Network interface 680 represents a NIC disposed within information handling system 600, on a main circuit board of the information handling system, integrated onto another component such as I/O interface 610, in another suitable location, or a combination thereof. Network interface device 680 includes network channels 682 and 684 that provide interfaces to devices that are external to information handling system 600. In a particular embodiment, network channels 682 and 684 are of a different type than peripheral channel 672 and network interface 680 translates information from a format suitable to the peripheral channel to a format suitable to external devices. An example of network channels 682 and 684 includes InfiniBand channels, Fibre Channel channels, Gigabit Ethernet channels, proprietary channel architectures, or a combination thereof. Network channels 682 and 684 can be connected to external network resources (not illustrated). The network resource can include another information handling system, a data storage system, another network, a grid management system, another suitable resource, or a combination thereof.

Management device 690 represents one or more processing devices, such as a dedicated baseboard management controller (BMC) System-on-a-Chip (SoC) device, one or more associated memory devices, one or more network interface devices, a complex programmable logic device (CPLD), and the like, which operate together to provide the management environment for information handling system 600. In particular, management device 690 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 600, such as system cooling fans and power supplies. Management device 690 can include a network connection to an external management system, and the management device can communicate with the management system to report status information for information handling system 600, to receive BIOS/UEFI or system firmware updates, or to perform other task for managing and controlling the operation of information handling system 600.

Management device 690 can operate off of a separate power plane from the components of the host environment so that the management device receives power to manage information handling system 600 when the information handling system is otherwise shut down. An example of management device 690 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 690 may further include associated memory devices, logic devices, security devices, or the like, as needed, or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

What is claimed is:

1. A light blocking air vent for an information handling system, the light blocking air vent comprising:
top and bottom surfaces; and
a plurality of components including first and second components, wherein the first component is in physical communication with the top surface and the second component is in physical communication with the bottom surface, the components creating a plurality of channels that allow airflow through the light blocking air vent, and the components preventing light from traveling from one edge of the light blocking air vent to another edge of the light blocking air vent.

2. The light blocking air vent of claim 1, wherein the plurality of components are covered with a coating, wherein the coating absorbs ultraviolet light.

3. The light blocking air vent of claim 2, wherein the coating has a matte finish to absorb the ultraviolet light.

4. The light blocking air vent of claim 2, wherein a texture of the coating disrupts reflections of the ultraviolet light.

5. The light blocking air vent of claim 1, wherein the plurality of components are fins and each different one of the plurality of channels is formed between adjacent pairs of the fins.

6. The light blocking air vent of claim 5, wherein the fins are in a zigzag shape.

7. The light blocking air vent of claim 5, wherein the fins are in a sinusoidal shape.

8. The light blocking air vent of claim 1, wherein the plurality of components are columns extending from the top surface to the bottom surface, and each different one of the plurality of channels is formed between adjacent pairs of the columns.

9. An information handling system comprising:
a chassis including top and bottom surfaces; and
a light blocking air vent in physical communication with the top and bottom surfaces of the chassis, the light blocking air vent including:
a plurality of components to create a plurality of channels, wherein the channels allow airflow through the light blocking air vent, and the components prevent light from traveling from one edge of the light blocking air vent to another edge of the light blocking air vent.

10. The information handling system of claim 9, wherein the plurality of components are covered with a coating, wherein the coating absorbs ultraviolet light.

11. The information handling system of claim 10, wherein the coating has a matte finish to absorb the ultraviolet light.

12. The information handling system of claim 10, wherein a texture of the coating disrupts reflections of the ultraviolet light.

13. The information handling system of claim 9, wherein the plurality of components are fins and each different one of the plurality of channels is formed between adjacent pairs of the fins.

14. The information handling system of claim 13, wherein the fins are in a zigzag shape.

15. The information handling system of claim 13, wherein the fins are in a sinusoidal shape.

16. The information handling system of claim 9, wherein the plurality of components creates a tamper resistance for the information handling system, wherein the tamper resistance prevents light outside of the information handling system from entering into the information handling system.

17. An information handling system comprising:
a chassis including top and bottom surfaces;
a liquid cooling system located within an interior of the chassis; and
a light blocking air vent in physical communication with the top and bottom surfaces of the chassis, the light blocking air vent including:
a plurality of components to create a plurality of channels that allow airflow through the light blocking air vent, the components preventing light from traveling from one edge of the light blocking air vent to another edge of the light blocking air vent, wherein the plurality of components creates a tamper resistance for the information handling system, wherein the tamper resistance prevents light outside of the information handling system from entering into the chassis.

18. The information handling system of claim 17, wherein the plurality of components are covered with a coating, wherein the coating absorbs ultraviolet light.

19. The information handling system of claim 18, wherein the coating has a matte finish to absorb the ultraviolet light.

20. The information handling system of claim 18, wherein a texture of the coating disrupts reflections of the ultraviolet light.
